(19) United States
(12) Patent Application Publication
(10) Pub. No.: US 2025/0175317 A1
(43) Pub. Date: May 29, 2025

(54) SELF-CLOCKED DUTY-CYCLE CORRECTED CURRENT-INTEGRATING PHASE INTERPOLATOR

(71) Applicant: Intel Corporation, Santa Clara, CA (US)

(72) Inventors: Soumya Bose, Hillsboro, OR (US); Chen Yuan, Vancouver (CA); Susnata Mondal, Hillsboro, OR (US); Mozhgan Mansuri, Portland, OR (US)

(21) Appl. No.: 18/520,415

(22) Filed: Nov. 27, 2023

(51) Int. Cl. H04L 7/00; H03K 5/156

(52) U.S. Cl. CPC H04L 7/0025; H03K 5/1565; H04L 7/0037

(57) ABSTRACT

Embodiments herein relate to a phase interpolator for interpolating phases of input clock signals. In a series of interpolating cells, each cell receives clock signals having a phase offset between them and outputs an interpolated clock signal having a phase between the phases of the input clock signals. The received clock signals control the on and off time for first and second current sources of the interpolator cell. Additionally, a pulldown transistor is controlled by an internally-generated clock signal from a previous cell in the series, and each cell outputs an internally-generated clock signal that is fed to the next cell in the series to control its pulldown transistor. As a result, the duty cycle of the interpolated clock signal is made constant. A programmable common mode voltage removes any systematic direct current (DC) error in transferring the pulldown signal from one interpolator cell to another.

### FIELD

The present application generally relates to the field of phase interpolators.

### BACKGROUND

A phase interpolator is a circuit used in communication systems to adjust the phase of a signal. A phase interpolator typically provides an output a clock signal having a phase which is formed from an interpolation of the phases of two input clock signals. It can be used in applications where precise phase alignment or phase shifting is required. However, various challenges are presented in efficiently operating a phase interpolator.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example circuit 100 in which a series of four interpolator cells 110 are used to provided interpolated clock signals V1_CKi to V4_CKi with different phases, where the interpolated clock signals can have large duty cycle variations, in accordance with various embodiments.

FIG. 2A depicts an example configuration of the interpolator cell 111 of FIG. 1, in accordance with various embodiments.

FIG. 2B depicts example plots 250, 260 and 270 of the clock signals CK_{0°} and CK_{90°} and the output voltage V1_CKi, respectively, of FIG. 2A versus time, showing a variation in duty cycle, in accordance with various embodiments.

FIG. 3 depicts an example circuit 300 in which a series of four interpolator cells 310 are used to provided interpolated clock signals V1_CKi to V4_CKi with different phases, where the interpolated clock signals have a fixed duty cycle based on the use of internally-generated, inter-cell clock signals, in accordance with various embodiments.

FIG. 4 depicts an example series of eight interpolator cells 400 used to provide respective clock signals with different phases, where the interpolated clock signals have a fixed duty cycle based on the use of internally-generated, inter-cell clock signals, in accordance with various embodiments.

FIG. 5 depicts an example implementation of the Current Digital-to-Analog Converter (IDAC) 120 of FIG. 3, in accordance with various embodiments.

FIG. 6 depicts an example implementation of the voltage generator 350 of FIG. 3, in accordance with various embodiments.

FIG. 7 depicts an example implementation of the interpolator cell 311 of FIG. 3, which is in a first quadrant of 0-90 degrees, in accordance with various embodiments.

FIG. 8 depicts an example implementation of the interpolator cell 312 of FIG. 3, which is in a second quadrant of 90-180 degrees, in accordance with various embodiments.

FIG. 9 depicts an example implementation of the interpolator cell 313 of FIG. 3, which is in a third quadrant of 180-270 degrees, in accordance with various embodiments.

FIG. 10 depicts an example implementation of the interpolator cell 314 of FIG. 3, which is in a fourth quadrant of 270-360 degrees, in accordance with various embodiments.

FIG. 11 depicts example plots 1100, 1110 and 1120 of the interpolated output clock V1_CKi, the input internal clock PI_{270°} and the output internal clock PI_{0°}, respectively, consistent with the interpolator cell 311 of FIG. 7, in accordance with various embodiments.

FIG. 12 depicts example plots 1200, 1210 and 1220 of the interpolated output clock V2_CKi, the input internal clock PI_{0°} and the output internal clock PI_{90°}, respectively, consistent with the interpolator cell 312 of FIG. 8, in accordance with various embodiments.

FIG. 13 depicts example plots 1300, 1310 and 1320 of the interpolated output clock V3_CKi, the input internal clock PI_{90°} and the output internal clock PI_{180°}, respectively, consistent with the interpolator cell 313 of FIG. 9, in accordance with various embodiments.

FIG. 14 depicts example plots 1400, 1410 and 1420 of the interpolated output clock V4_CKi, the input internal clock PI_{180°} and the output internal clock PI_{270°}, respectively, consistent with the interpolator cell 314 of FIG. 10, in accordance with various embodiments.

FIG. 15 depicts example plots 1500, 1510, 1520 and 1530 of CK_{0°}, CK_{90°}, CK_{180°} and CK_{270°}, respectively, consistent with FIGS. 7-14, in accordance with various embodiments.

FIG. 16A depicts an example plot of the duty cycle of the internal clock signal PI_{0°} versus the decimal equivalent of a 7-bit PI code, consistent with FIGS. 7-10, in accordance with various embodiments.

FIG. 16B depicts an example plot of the duty cycle of the internal clock signal PI_{90°} versus the decimal equivalent of a 7-bit PI code, consistent with FIGS. 7-10, in accordance with various embodiments.

FIG. 16C depicts an example plot of the duty cycle of the internal clock signal PI_{180°} versus the decimal equivalent of a 7-bit PI code, consistent with FIGS. 7-10, in accordance with various embodiments.

FIG. 16D depicts an example plot of the duty cycle of the internal clock signal PI_{270°} versus the decimal equivalent of a 7-bit PI code, consistent with FIGS. 7-10, in accordance with various embodiments.

FIG. 17 illustrates an example of components that may be present in a computing system 1750 for implementing the techniques (e.g., operations, processes, methods, and methodologies) described herein.

### DETAILED DESCRIPTION

As mentioned at the outset, various challenges are presented in efficiently operating a phase interpolator.

A phase interpolator (PI) rotates a clock by shifting the clock phase in fine steps. It is used in various applications such as high-speed data communications, phased array transmitters and time-of-flight computations. In data communications, it is primarily used to synchronize the clock phase with respect to data and minimize sampling errors.

A PI can be implemented using current-mode analog mixers which require sinusoidal input clocks. A complementary metal-oxide semiconductor (CMOS) inverter-based PI can be used with square wave clocks and consume less power. However, its linearity is largely dependent on the input clock slew. A better alternative is a current-integrating PI, which uses multiple phases of the input clock and a code-dependent current source for digital-to-time encoding (phase interpolation) by charging or discharging a capacitor (e.g., current integration). The interpolation, which is primarily controlled by current charging, can be power efficient. However, single-edge integration with a multi-phase input clock results in code-dependent duty-cycle distortion, requiring additional correction stages.

One possible solution involves combining interpolated edges from multiple current integrators with complementary clocks. However, using a combination of interpolated edges requires multiple phase interpolators as well as additional edge-combining circuits, and results in increased power consumption. In addition, it is not a scalable solution, as meeting the timing margin of the edge combining circuits becomes very challenging at high frequencies.

Another possible solution involves dual-edge interpolation using bidirectional current charging and discharging or full CMOS interpolation. However, dual-edge interpolation using source and sink current sources for charging and discharging requires additional code-controlled current sources. Also, it requires tight control of the integration time to avoid a short-circuit path between supply and ground during the transition from the charging to the discharging phase. Moreover, in either of the solutions, each of the input clock phases is loaded by multiple stages which results in higher power consumption in the preceding stages as well.

The solutions provided herein address the above and other issues. In one aspect, a PI circuit is provided which uses a self-clocked duty-cycle error correction technique in which multiple phases of the interpolated edge are leveraged to generate a proportional shift in the non-interpolated edge and self-correct the duty-cycle. The solution eliminates additional current integration and reduces overall power consumption.

In one approach, the PI enables power-efficient phase interpolation using single-edge current integration. The proposed circuit architecture reduces the loading on multiple phases of the input clock to half by only controlling the charging (or discharging) phase to shift the output clock edge. The single interpolated edges of multiple clock phases are re-utilized to generate a proportional shift in the discharging (or charging) edge and self-correct the duty-cycle of the output clock phases. This eliminates the need for additional duty-cycle correcting circuits and reduces the clock loading at the input of the PI, hence reducing the overall power consumption of the clock distribution.

The solutions provide a number of advantages. For example, as data rates increase, the data sampling timing margin reduces, which necessitates fine control/rotation of the clock phases, employing a scalable and power efficient phase interpolator. This solutions introduce a scalable phase interpolator that uses only single-edge current integration and self-corrects the duty-cycle distortion, resulting in a power efficient phase interpolation and preceding clock buffers. Various products can take advantage of this scalable energy-efficient PI solution to accurately sample the data. These products include a Peripheral Component Interconnect Express (PCIe) high-speed serial computer expansion bus, a serializer/deserializer (SerDes) integrated circuit transceiver that converts parallel data to serial data and vice-versa, and silicon photonics (SiPh) optical links.

These and other features will be further apparent in view of the following discussion.

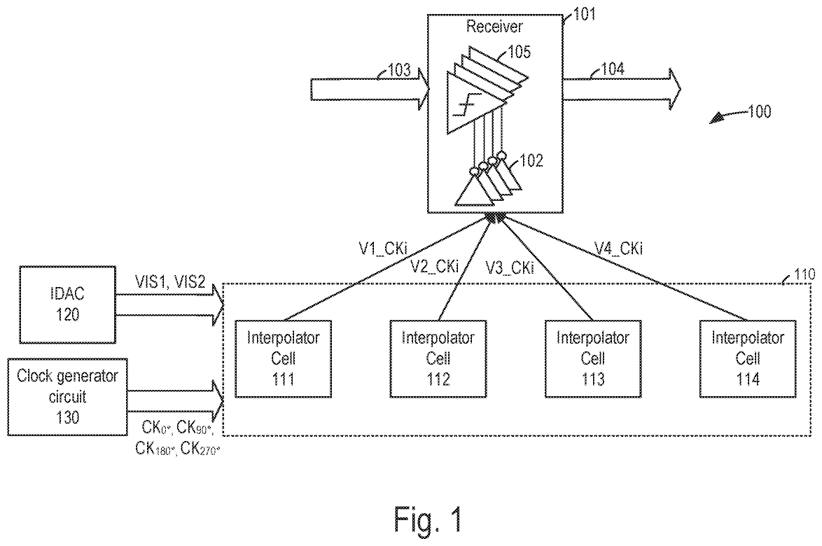

FIG. 1 depicts an example circuit 100 in which a series of interpolator cells 110 are used to provided interpolated clock signals V1_CKi-V4_CKi with different phases, in accordance with various embodiments. The series of interpolator cells includes four cells in this example, including cells 111, 112, 113 and 114, which are associated with phase quadrants of 0-90 degrees, 90-180 degrees, 180-270 degrees and 270-360 degrees, respectively. Each interpolator cell receives first and second voltages, VIS1 and VIS2, respectively, from a current digital-to-analog converter (IDAC) 120. An IDAC is a type of digital-to-analog converter (DAC) that converts digital input data into a corresponding analog current. VIS1 and VIS2 are the gate voltages required for the first and second current sources, respectively, in each interpolator cell. The interpolator cells also receive multi-phase clock signals from a clock generator circuit 130, where the phases of the clock signals are offset from one another by 90 degrees. In one approach, the cell 111 receives CK0° and CK90°, the cell 112 receives CK90° and CK180°, the cell 113 receives CK180° and CK270° and the cell 114 receives CK270° and CK0°. CK denotes a clock signal and the subscript denotes the phase of the clock signals in degrees.

Each interpolator cell outputs an interpolated clock signal (CKi) having a phase which is formed by interpolating between the phases of the two received clock signals. For example, the cell 111 outputs V1_CKi which has a phase between 0-90 degrees, the cell 112 outputs V2_CKi which has a phase between 90-180 degrees, the cell 113 outputs V3_CKi which has a phase between 180-270 degrees, and the cell 114 outputs V4_CKi which has a phase between 270-360 degrees (0 degrees=360 degrees). The interpolated clock signals may be output to a receiver 101, for example, via respective buffers 102. The receiver 101 receives an input serial data signal 103 and uses the interpolated clock signals to recover corresponding parallel data signals 104. This is done by sampling the input data signal with properly aligned clocks from the phase interpolator cells 110 as buffered by the buffers 102. The data flow is primarily through the samplers 105.

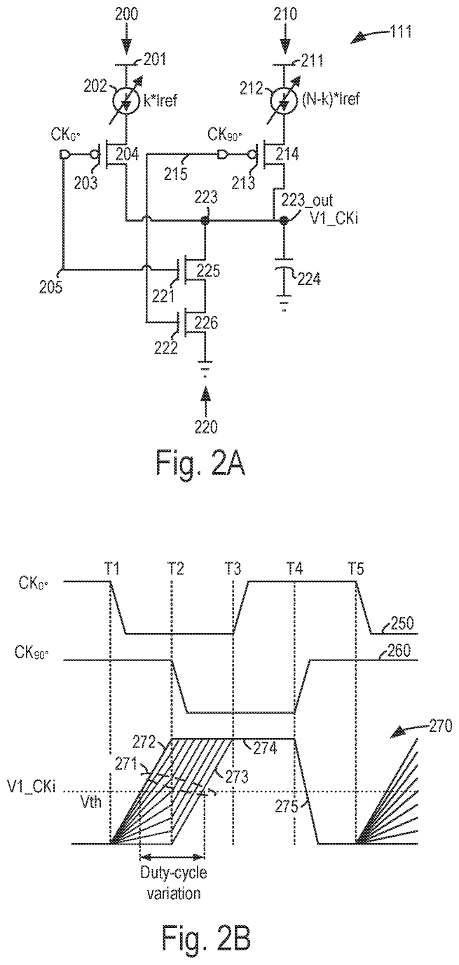

FIG. 2A depicts an example configuration of the interpolator cell 111 of FIG. 1, in accordance with various embodiments. Each interpolator cell may be configured similarly where, as mentioned, each cell receives a set of two different clock signals which are offset in phase by 90 degrees. The interpolator cell 111 includes a first path 200 and a second path 210 in parallel. The first path includes a current source 202 which provides a current k*Iref, where Iref is a reference current in the IDAC, using power from a power supply node 201. The current source is mirrored from a current source in the IDAC. In one approach, the current source 202 is formed by a p-type metal-oxide-semiconductor field-effect transistor (pMOSFET) which receives a first control gate voltage, VIS1, from the IDAC. The current in the first path is modulated by a transistor 204 (also a pMOSFET in this example) which receives CK_{0°} from the clock generator circuit. When CK_{0°} is low, e.g., at or near 0 V, the transistor 204 is conductive, or on, so that the current from the current source 202 can flow to a pulldown node 223 which is coupled to both the first and second paths.

The second path includes a current source 212 which provides a current (N−k)*Iref, using power from a power supply node 211. “k” and “N” are integers used by the IDAC to allocate a portion of Iref to the first and second paths of the interpolator cell, where k≤N. Specifically, Iref*k/N is allocated to the first path and Iref*(N−k)/N is allocated to the second path. In one approach, the current source 212 is formed by a pMOSFET which receives a second control gate voltage, VIS2, from the IDAC. The current in the second path is modulated by a transistor 214 (also a pMOSFET in this example) which receives CK_{90°} from the clock generator circuit. When CK_{90°} is low, the transistor 214 is conductive so that the current from the current source 212 can flow to the pulldown node 223. The pulldown node 223 includes an output node 223_out at which the voltage V1_CKi is output. A capacitor 224 represents a parasitic capacitance at the output.

The interpolator cell 111 further includes a pulldown path 220 (a third path) which is coupled to the first and second paths at the pulldown node 223 at one end and grounded at the other end. The pulldown path includes pulldown transistors 225 and 226 which are n-type MOSFETs (nMOSFETs) in this example. A control gate 221 of the transistor 225 is coupled to the control gate 203 of the transistor 204 via a path 205 to receive CK_{0°}, and a control gate 222 of the transistor 226 is coupled to the control gate 213 of the transistor 214 via a path 215 to receive CK_{90°}. Accordingly, the clock signals are each provided to two transistors. When CK_{0°} and CK_{90°} are both low, the currents from the first and second paths combined can flow to the pulldown path. When one or both of CK_{0°} and CK_{90°} are high, current cannot flow to the pulldown path.

When current flows in the first and second paths but not the pulldown path, the pulldown node is charged up so that V1_CKi increases. When current does not flow in the first or second path but does flow in the pulldown path, the pulldown node discharges so that V1_CKi decreases. Accordingly, the low to high cycling of the clock signals CK_{0°} and CK_{90°} results in a corresponding cycling of V1_CKi. Moreover, the phase of V1_CKi is between the phases of CK_{0°} and CK_{90°} based on the values of k and N. When k is relatively large, the phase of V1_CKi is relatively close to the phase of CK_{0°}. When k is relatively small, the phase of V1_CKi is relatively close to the phase of CK_{90°}. See also FIG. 2B.

FIG. 2B depicts example plots 250, 260 and 270 of the clock signals CK_{0°} and CK_{90°} and the output voltage V1_CKi, respectively, of FIG. 2A versus time, showing a variation in duty cycle, in accordance with various embodiments. T1-T5 are equally spaced time points. The plot 250 shows that CK_{0°} goes low from T1-T3 and returns high at T3-T5. The plot 260 shows that CK_{90°} goes low from T2-T4 and returns high starting at T4. The plots 270 include a set of plots 271 which show V1_CKi increasing with different phases. The set of plots 271 include a plot 272 which represents no phase delay and a plot 273 which represents a phase delay of T2-T1. A plot 274 depicts a peak level of V1_CKi, and a plot 275 depicts V1_CKi decreasing at T4. When CK_{0°} is low, the current in the first path of the interpolator cell can flow to the pulldown node to increase V1_CKi at T1-T2. The plot 272 corresponds to the highest rate of increase of V1_CKi from T1-T2, corresponding to k=N. The plot 273 corresponds to the lowest rate of increase (e.g., zero) of V1_CKi from T1-T2, corresponding to k=0.

At T2, CK_{90°} also goes low so that the current in the second path of the interpolator cell can also flow to the pulldown node to increase V1_CKi at a faster rate compared to the rate at T1-T2. The rate of increase of V1_CKi is fixed at T2-T3 regardless of the value of k since the current Iref (the sum of the currents in the first and second paths) flows to the pulldown node regardless of the value of k. When CK_{90°} goes high at T4, the current flow to the pulldown node is cutoff, and the pulldown node is coupled to ground, so that V1_CKi decreases. The time and rate of this decrease is also independent of the value of k.

Accordingly, the duty cycle of V1_CKi can vary based on the value of k. In one approach, when V1_CKi is received at one of the buffers 102 in FIG. 1, the duty cycle of an output signal of the buffer can vary as indicated based on the threshold voltage (Vth) of the buffer. When k is larger, the duty cycle is longer.

In further detail, there is a distortion or variation in the duty-cycle of the output clock of the interpolation cell in a single-edge current integration-based phase interpolation. Phase interpolation of a single edge of the output clock can be performed using the interpolator cell 111 of FIG. 2A. The interpolator cell includes two pMOSFET switches that control the total charging current based on the input phases and the IDAC. Note that the charging phase is interpolated here. Alternatively, the single edge interpolation can be performed in the discharging phase. During the non-overlapping phase of CK_{0°} and CK_{90°}, at T1-T2, the output V1_CKi is charged with a varying slope based on the IDAC code (k). At the end of this cycle, at T2, V1_CKi reaches a voltage which is directly proportional to the IDAC current (k*Iref).

In the overlapping phase, T2-T3, both pMOSFET transistors are on, so that the output node is charged with a constant current, N*Iref, independent of the IDAC code (k), resulting in a constant voltage slope. The varying initial voltage at the onset of the constant-slope rising edge of V1_CKi in T2-T3 will result in phase interpolation based on the threshold voltage (Vth) of the next stage buffer. Discharging of the output node can be done on the overlapping high-phase (T4-T5) of the input clocks, resulting in a same falling edge of V1_CKi, independent of the PI code (i.e., for all codes of the IDAC). The time difference between the rising edge (proportional to the IDAC code) and the falling edge (constant/independent of the IDAC code) results in a PI code-dependent duty-cycle error in V1_CKi and subsequent buffered outputs. The worst-case duty-cycle error is 75% for the maximum value of k (=N), which requires excess bandwidth (˜2×) if it is not corrected.

A solution is proposed that re-utilizes the multi-phase interpolating edges of the output clock to delay the non-interpolating edges of the adjacent clock phases, proportionally making the duty-cycle of the output clocks constant and independent of the PI code. Simulation results are shown to demonstrate the advantages of the solution.

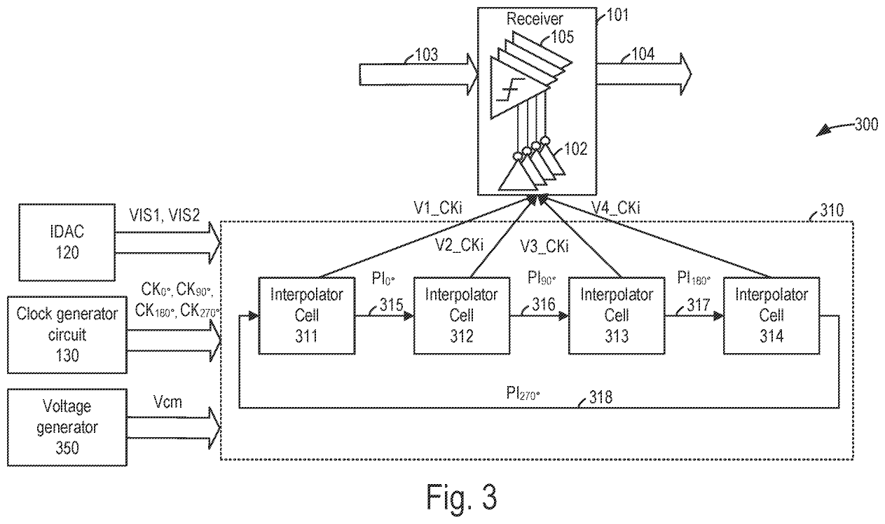

FIG. 3 depicts an example circuit 300 in which a series of four interpolator cells 310 are used to provided interpolated clock signals V1_CKi to V4_CKi with different phases, where the interpolated clock signals have a fixed duty cycle based on the use of internally-generated, inter-cell clock signals, in accordance with various embodiments.

The series of interpolator cells includes four cells in this example, including cells 311, 312, 313 and 314, which are associated with phase quadrants of 0-90 degrees, 90-180 degrees, 180-270 degrees and 270-360 degrees, respectively. Each interpolator cell receives first and second voltages, VIS1 and VIS2, respectively, from the IDAC 120. Similar to FIG. 1, the cell 311 receives CK_{0°} and CK_{90°}, the cell 312 receives CK_{90°} and CK_{180°}, the cell 313 receives CK_{180°} and CK_{270°} and the cell 314 receives CK_{270°} and CK_{0°}.

Each interpolator cell outputs an interpolated clock signal (CKi) having a phase which is formed by interpolating between the phases of the two received clock signals. For example, the cell 311 outputs V1_CKi which has a phase between 0-90 degrees, the cell 312 outputs V2_CKi which has a phase between 90-180 degrees, the cell 313 outputs V3_CKi which has a phase between 180-270 degrees, and the cell 314 outputs V4_CKi which has a phase between 270-360 degrees. The interpolated clock signals may be output to the receiver 101, for example, via the respective buffers 102. The receiver receives an input signal 103 and uses the interpolated clock signals to recover a corresponding data signal 104.

Each interpolator cell also receives an internal clock signal from a closest previous cell in the series, and outputs an internal clock signal to a closest next cell in the series. For example, the cell 311 receives PI_{270°} from the previous cell 314 on a path 318, and outputs PI_{0°} to the next cell 312 on a path 315. The cell 312 receives PI_{0°} from the previous cell 311 on the path 315, and outputs PI_{90°} to the next cell 313 on a path 316. The cell 313 receives PI_{90°} from the previous cell 312 on the path 316, and outputs PI_{180°} to the next cell 314 on a path 317. Finally, the cell 314 receives PI_{180°} from the previous cell 313 on the path 317, and outputs PI_{270°} to the next cell 311 on the path 318. The previous cell of a given cell refers to the immediately previous cell in a consecutive order of the series of cells. The next cell of a given cell refers to the immediately following cell in the consecutive order of the series of cells.

The clock signals PI_{0°}, PI_{90°}, PI_{180°} and PI_{270°} are internally generated within the interpolator cells rather than being received from an external circuit, in one approach. The cells each also receive a common mode voltage Vcm from a voltage generator 350. The phases of the internal clock signals are offset by 90 degrees in this example, or generally, by 360/m degrees relative to one another, where m is the number of interpolator cells in the series.

Each interpolator cell comprises a circuit.

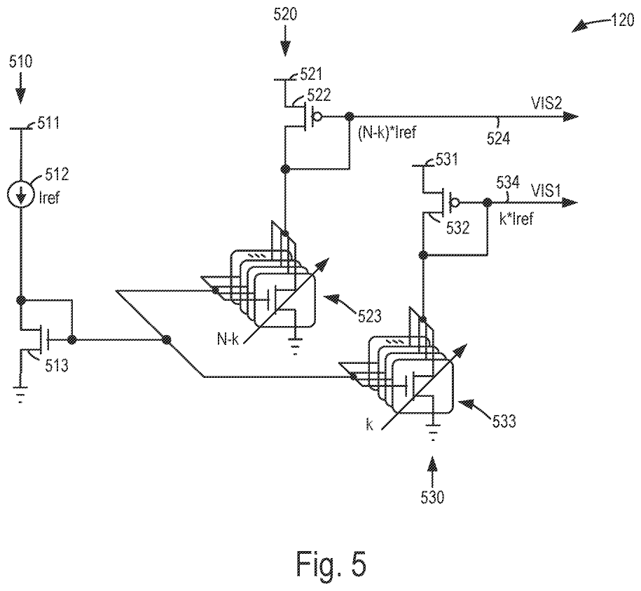

An example implementation of the IDAC 120 is provided in FIG. 5.

The clock generator circuit 130 is an electronic oscillator that produces a clock signal for use in synchronizing a circuit's operation. The signal can be a square wave, for example. The clock generator circuit may include a resonant circuit and an amplifier. The resonant circuit can be a quartz piezo-electric oscillator, for instance. The amplifier circuit inverts the signal from the oscillator and feeds a portion back into the oscillator to maintain oscillation. The generator may have additional sections to modify the basic signal, such as a frequency divider or clock multiplier. In an example implementation, a programmable clock generator circuit is used. This allows the number used in the divider or multiplier to be changed so that a variety of output frequencies can be selected without modifying the hardware.

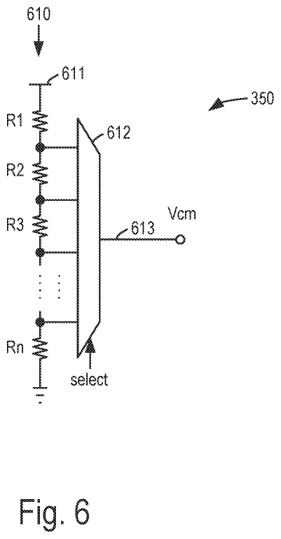

An example implementation of the voltage generator 350 is provided in FIG. 6.

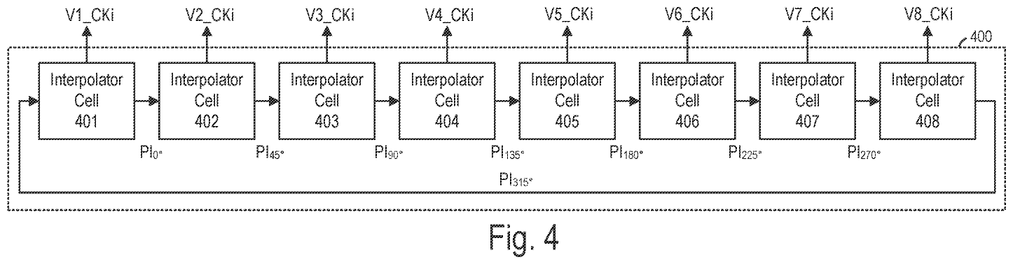

FIG. 4 depicts an example series of eight interpolator cells 400 used to provide respective clock signals with different phases, where the interpolated clock signals have a fixed duty cycle based on the use of internally-generated, inter-cell clock signals, in accordance with various embodiments. The number of interpolator cells used in a series can vary, e.g., to include 4, 6 or 8. For example, the approach can be extended to six interpolator cells with a six-way interleaved clocking as well. When eight cells are used, the phases of the internal clock signals are offset by 45 degrees or 360/m degrees, where m=8. The interpolator cells 401, 402, 403, 404, 405, 406, 407 and 408 output interpolated clock signals V1_CKi, V2_CKi, V3_CKi, V4_CKi, V5_CKi, V6_CKi. V7_CKi and V8_CKi, respectively, to a receiver. The internal clocks input to the cells by the previous cell are PI₃₁₅°, PI_{0°}, PI_{45°}, PI_{90°}, PI_{135°}, PI_{180°}, PI_{225°} and PI_{270°} for cells 401-408, respectively. The internal clocks output by the cells to the next cell are PI_{0°}, PI_{45°}, PI_{90°}, PI_{135°} PI_{180°}, PI_{225°}, PI_{270°} and PI₃₁₅° for cells 401-408, respectively.

FIG. 5 depicts an example implementation of the Current Digital-to-Analog Converter (IDAC) 120 of FIG. 3, in accordance with various embodiments. The IDAC outputs voltages VIS1 and VIS2 to provide a current source for first and second paths, respectively, of each interpolator cell. VIS1 and VIS2 are generated based on a code of the IDAC indicated by the values k and N. A control circuit can be used to set these values, in one approach, after a tuning process. The tuning process can include simulations which optimize the values. A first path 510 of the IDAC includes a power supply node 511, a current source 512 which provides a reference voltage, Iref, and a diode-connected transistor 513 (e.g., an nMOSFET) coupled to ground. This path flows the current Iref. A diode-connected transistor has a resistive load and can be used in a current mirror to provide a voltage drop that tracks a voltage drop in other transistors as temperature changes. A second path 520 of the IDAC includes a power supply node 521, a diode-connected transistor 522 (e.g., a pMOSFET), and a set of transistors 523 (nMOSFETs) which can be switched in or out based on the value N-k. VIS2, on the path 524, which is coupled to the control gate of the transistor 522, is an output of the second path. A third path 530 of the IDAC includes a power supply node 531, a diode-connected transistor 532 (e.g., a pMOSFET), and a set of transistors 533 (nMOSFETs) which can be switched in or out based on the value k. VIS1, on the path 534, which is coupled to the control gate of the transistor 532, is an output of the third path. As mentioned, VIS1 and VIS2 can be provided to each of the interpolator cells.

In an example implementation, the IDAC is to control a first current source in each interpolator cell to provide a current of k*Iref and to control a second current source in each interpolator cell to provide a current of (N−k)*Iref, where Iref is a reference current, k is an integer, N is an integer and k≤N.

FIG. 6 depicts an example implementation of the voltage generator 350 of FIG. 3, in accordance with various embodiments. The voltage generator can be a programmable common mode voltage generator which outputs a voltage Vcm to each of the interpolator cells. The voltage generator can be implemented as an n-bit Resistor string Digital-To-Analog Converter (RDAC) in which a path 610 includes a power supply node 611 and a series of resistors R1, R2, R3, . . . , Rn, where nodes between the resistors are input to a multiplexer 612. Based on a select signal, the multiplexer outputs Vcm on a path 613.

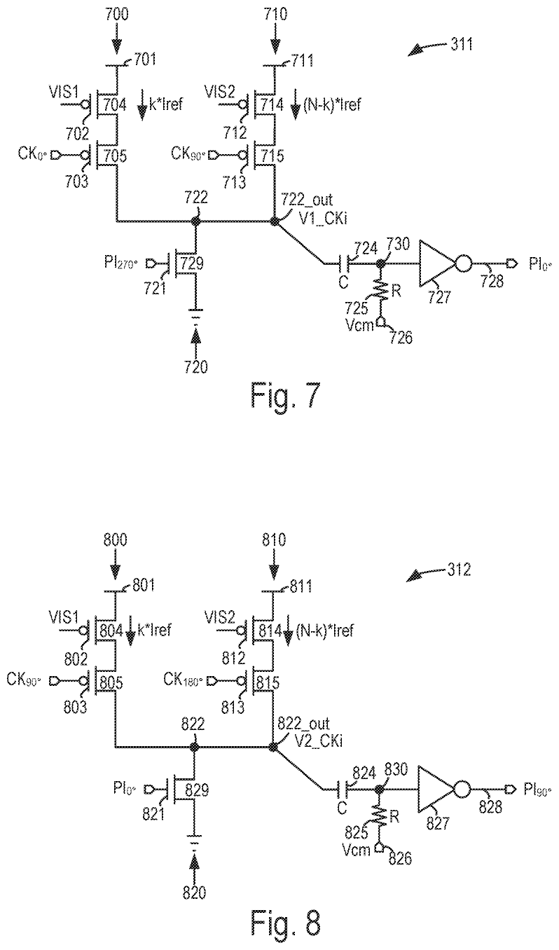

FIG. 7 depicts an example implementation of the interpolator cell 311 of FIG. 3, which is in a first quadrant of 0-90 degrees, in accordance with various embodiments. A first path 700 includes a power supply node 701, a first current source, e.g., a pMOSFET transistor 704 which receives VIS1 on its control gate 702 to provide a current k*Iref, and a first clocked transistor 705 which receives CK_{0°} on its control gate 703. A second path 710 includes a power supply node 711, a second current source, e.g., a pMOSFET transistor 714 which receives VIS2 on its control gate 712 to provide a current (N−k)*Iref, and a second clocked transistor 715 which receives CK_{90°} on its control gate 713. A pulldown path 720 is coupled to the first and second paths at a pulldown node 722, and includes a pulldown transistor 729 (e.g., an nMOSFET) which receives PI_{270°} on its control gate 721 from the previous cell in the series. The source terminal of the pulldown transistor is coupled to ground while the drain terminal is coupled to the pulldown node.

The pulldown transistors in FIGS. 7-10 are also clocked transistors because they receive a clock signal. The clocked transistors are examples of clocked switches.

The interpolated voltage V1_CKi is output from the interpolator cell at an output node 722_out of the pulldown node. The pulldown node is coupled to an inverter 727 via a capacitor 724 having a capacitance C to alternating current (AC) couple the signal from node 722_out to node 730. A node 730 between the capacitor and the inverter is coupled to Vcm at node 726 via a resistor 725. The inverter 727 provides its internally generated signal PI_{0°} on an output path 728 which is coupled to the next cell in the series.

In the interpolation cell 311, the two pMOSFETs 705 and 715 are loaded with respective input clock phases/signals as in FIG. 2A, but only one pull down nMOSFET 729 is used and that pulldown transistor is not loaded with either of the input clock phases/signals. Instead, an internally generated clock (e.g., PI_{270°}) drives the pulldown transistor 729. Thus, CK_{0°} and CK_{90°} are each only provided to one transistor, in this example.

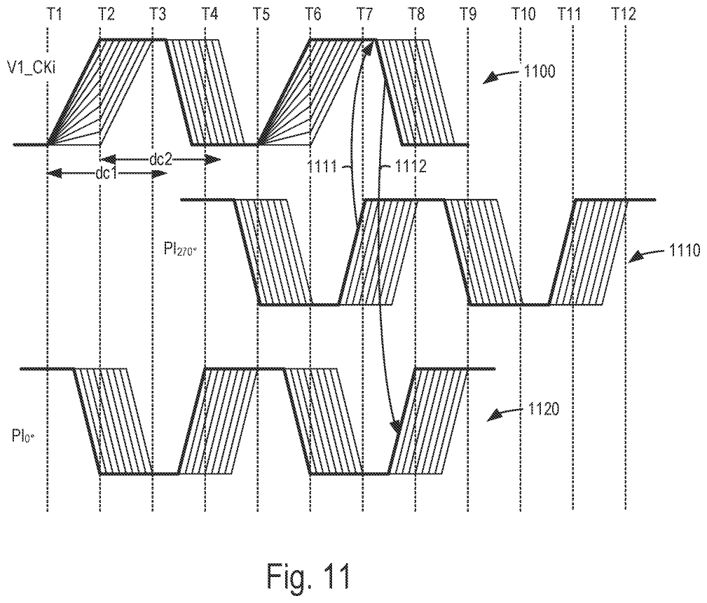

In a transceiver with a multi-rate (or interleaving) architecture, multiple phases of the sampling clock are used (for instance quadrature clock phases in a quarter-rate architecture). For a quarter phased (four-phase) clock, the interpolation is handled separately in one of four quadrants for generating each of the four output clock phases. Each interpolation cell takes two adjacent input clock phases (e.g., CK_{0°} and CK_{90°}) and interpolates in a respective quadrant. The proposed design provides self-clocked duty-cycle correction. In particular, the output (V1_CKi) of the interpolator cell 311 in the first quadrant (Quad-I) is buffered by an inverter 727 whose output (PI_{0°}) is fed to the pulldown nMOSFET of the interpolation cell 312 of the adjacent quadrant (Quad-II) as illustrated in FIG. 3. Similarly, the interpolated output (V2_CKi) of the adjacent cell 312 is passed to the pulldown nMOSFET of the next cell 313, and this is continued cyclically. As a result, the interpolated charging edges of the clock signals V1_CKi, V2_CKi, V3_CKi and V4_CKi, propagate through the internal buffers and generate proportional shifts in the falling edges of the output clock phases, as explained also in connection with FIGS. 11-14.

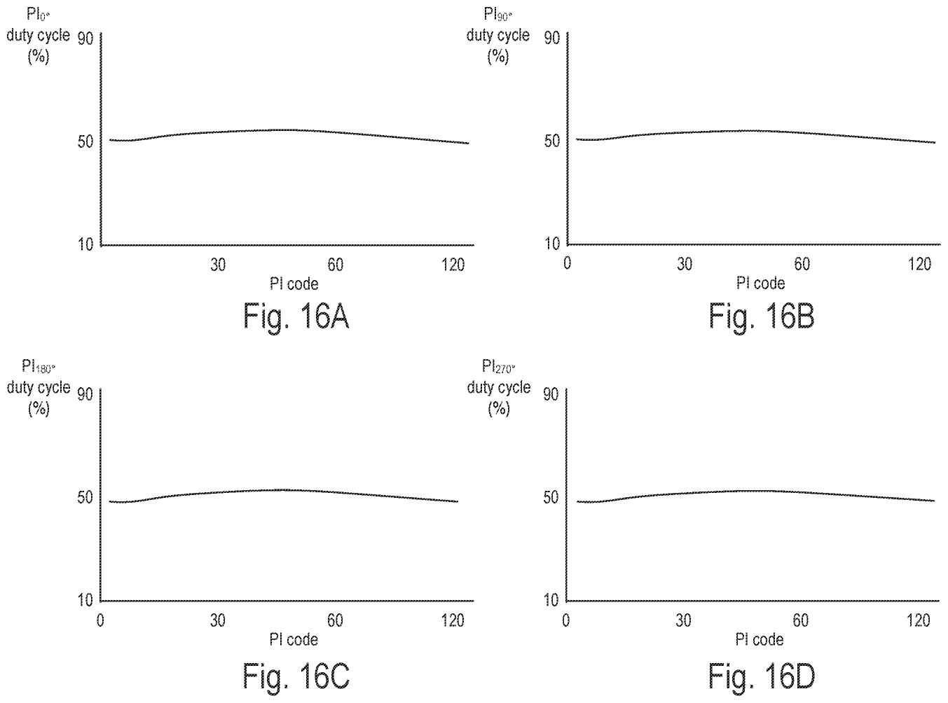

As depicted in FIGS. 16A-16D, the resulting output clocks achieve a clean 50% duty-cycle due to the closed-loop feedback. The single-edge integration-based interpolation can be performed on the output discharging phase as well and proportional rising edges can be generated by propagating the interpolated falling edges. The interpolated signals (V1_CKi to V4_CKi) are capacitively coupled to the inverter buffers whose input common-mode voltage (Vcm) is programmable to remove any systematic error due to the threshold variation of the inverter. The interpolated duty-cycle distortion free output clocks, e.g., PI_{0°}, PI_{90°}, PI_{180°} and PI_{270°} are further buffered out in the clock propagation chain. While the self-clocked duty cycle error correction is explained here with quarter phase (four-phase) clocks the idea can be extended to six- or eight-phase clocks.

FIG. 8 depicts an example implementation of the interpolator cell 312 of FIG. 3, which is in a second quadrant of 90-180 degrees, in accordance with various embodiments. A first path 800 includes a power supply node 801, a first current source, e.g., a pMOSFET transistor 804 which receives VIS1 on its control gate 802 to provide a current k*Iref, and a first clocked transistor 805 which receives CK_{90°} on its control gate 803. A second path 810 includes a power supply node 811, a second current source, e.g., a pMOSFET transistor 814 which receives VIS2 on its control gate 812 to provide a current (N−k)*Iref, and a second clocked transistor 815 which receives CK_{180°} on its control gate 813. A pulldown path 820 is coupled to the first and second paths at a pulldown node 822, and includes a pulldown transistor 829 (e.g., an nMOSFET) which receives PI_{0°} on its control gate 821 from the previous cell in the series.

The interpolated voltage V2_CKi is output from the interpolator cell at an output node 822_out of the pulldown node. The pulldown node is coupled to an inverter 827 via a capacitor 824 (C). A node 830 between the capacitor and the inverter is coupled to Vcm at node 826 via a resistor 825. The inverter 827 provides its internally generated signal PI_{90°} on an output path 828 which is coupled to the next cell in the series.

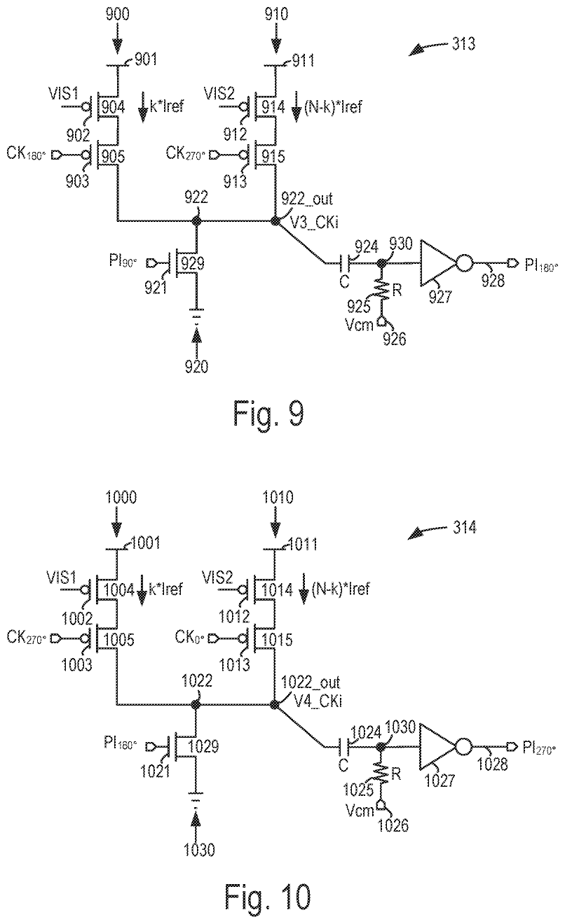

FIG. 9 depicts an example implementation of the interpolator cell 313 of FIG. 3, which is in a third quadrant of 180-270 degrees, in accordance with various embodiments. A first path 900 includes a power supply node 901, a first current source, e.g., a pMOSFET transistor 904 which receives VIS1 on its control gate 902 to provide a current k*Iref, and a first clocked transistor 905 which receives CK_{180°} on its control gate 903. A second path 910 includes a power supply node 911, a second current source, e.g., a pMOSFET transistor 914 which receives VIS2 on its control gate 912 to provide a current (N−k)*Iref, and a second clocked transistor 915 which receives CK_{270°} on its control gate 913. A pulldown path 920 is coupled to the first and second paths at a pulldown node 922, and includes a pulldown transistor 929 (e.g., an nMOSFET) which receives PI_{90°} on its control gate 921 from the previous cell in the series.

The interpolated voltage V2_CKi is output from the interpolator cell at an output node 922_out of the pulldown node. The pulldown node is coupled to an inverter 927 via a capacitor 924 (C). A node 930 between the capacitor and the inverter is coupled to Vcm at node 926 via a resistor 925. The inverter 927 provides its internally generated signal PI_{180°} on an output path 928 which is coupled to the next cell in the series.

FIG. 10 depicts an example implementation of the interpolator cell 314 of FIG. 3, which is in a fourth quadrant of 270-360 degrees, in accordance with various embodiments. A first path 1000 includes a power supply node 1001, a first current source, e.g., a pMOSFET transistor 1004 which receives VIS1 on its control gate 1002 to provide a current k*Iref, and a first clocked transistor 1005 which receives CK_{270°} on its control gate 1003. A second path 1010 includes a power supply node 1011, a second current source, e.g., a pMOSFET transistor 1014 which receives VIS2 on its control gate 1012 to provide a current (N−k)*Iref, and a second clocked transistor 1015 which receives CK_{0°} on its control gate 1013. A pulldown path 1020 is coupled to the first and second paths at a pulldown node 1022, and includes a pulldown transistor 1029 (e.g., an nMOSFET) which receives PI_{180°} on its control gate 1021 from the previous cell in the series.

The interpolated voltage V2_CKi is output from the interpolator cell at an output node 1022_out of the pulldown node. The pulldown node is coupled to an inverter 1027 via a capacitor 1024 (C). A node 1030 between the capacitor and the inverter is coupled to Vcm at node 1026 via a resistor 1025. The inverter 1027 provides its internally generated signal PI_{270°} on an output path 1028 which is coupled to the next cell in the series.

FIG. 11 depicts example plots 1100, 1110 and 1120 of the interpolated output clock V1_CKi, the input internal clock PI_{270°} and the output internal clock PI_{0°}, respectively, consistent with the interpolator cell 311 of FIG. 7, in accordance with various embodiments. FIGS. 11-14 depicts plots of voltage versus time, where the time scale includes time points T1-T12. The voltages are depicted over two clock cycles rather than throughout the time scale for simplicity. In a first cycle, V1_CKi increases (is charged) at a time between T1 and T2 based on k. However, the time of the decrease (discharge) is shifted correspondingly so that the duty cycle is fixed regardless of k. For example, dc1 and dc2 represent the equal duty cycles with k=N and k=0, respectively. Additionally, the arrow 1111 shows that when PI_{270°} increases, the pulldown transistor is turned on (conductive) so that the pulldown node (at V1_CKi) starts to discharge, after a small delay due to parasitic capacitance. PI_{270°} thus controls the time at which V1_CKi discharges. The arrow 1112 shows that when V1_CKi decreases, the output internal clock signal PI_{0°} increases, after a small delay due to parasitic capacitance. PI_{0°} is therefore essentially the inverse of V1_CKi with a small delay.

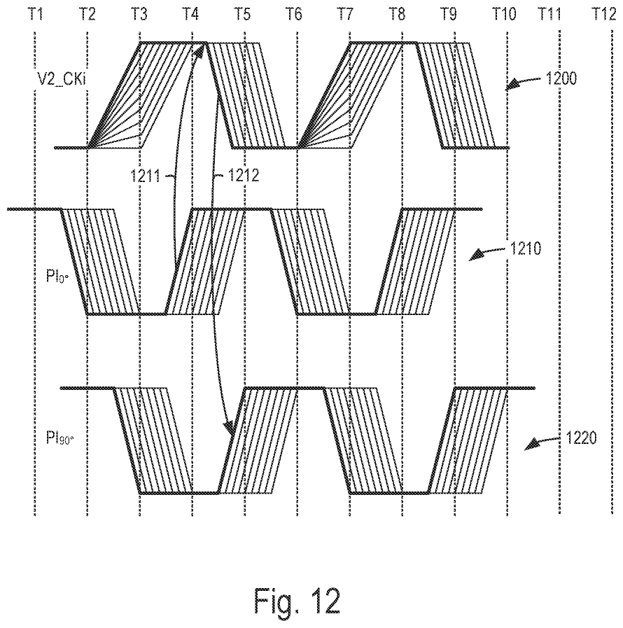

FIG. 12 depicts example plots 1200, 1210 and 1220 of the interpolated output clock V2_CKi, the input internal clock PI_{0°} and the output internal clock PI_{90°}, respectively, consistent with the interpolator cell 312 of FIG. 8, in accordance with various embodiments. In a first cycle, V2_CKi increases at a time between T2 and T3 based on k. As before, the time of the decrease is shifted correspondingly so that the duty cycle is fixed regardless of k. Additionally, the arrow 1211 shows that when PI_{0°} increases, the pulldown transistor is turned on so that the pulldown node (at V2_CKi) starts to discharge, after a small delay due to parasitic capacitance. PI_{0°} thus controls the time at which V2_CKi discharges. The arrow 1212 shows that when V2_CKi decreases, the output internal clock signal PI_{90°} increases, after a small delay due to parasitic capacitance. PI_{90°} is therefore essentially the inverse of V2_CKi with a small delay.

FIG. 13 depicts example plots 1300, 1310 and 1320 of the interpolated output clock V3_CKi, the input internal clock PI_{90°} and the output internal clock PI_{180°}, respectively, consistent with the interpolator cell 313 of FIG. 9, in accordance with various embodiments. In a first cycle, V3_CKi increases at a time between T3 and T4 based on k. As before, the time of the decrease is shifted correspondingly so that the duty cycle is fixed regardless of k. Additionally, the arrow 1311 shows that when PI_{90°} increases, the pulldown transistor is turned on so that the pulldown node (at V3_CKi) starts to discharge, after a small delay due to parasitic capacitance. PI_{90°} thus controls the time at which V3_CKi discharges. The arrow 1312 shows that when V3_CKi decreases, the output internal clock signal PI_{180°} increases, after a small delay due to parasitic capacitance. PI_{180°} is therefore essentially the inverse of V3_CKi with a small delay.

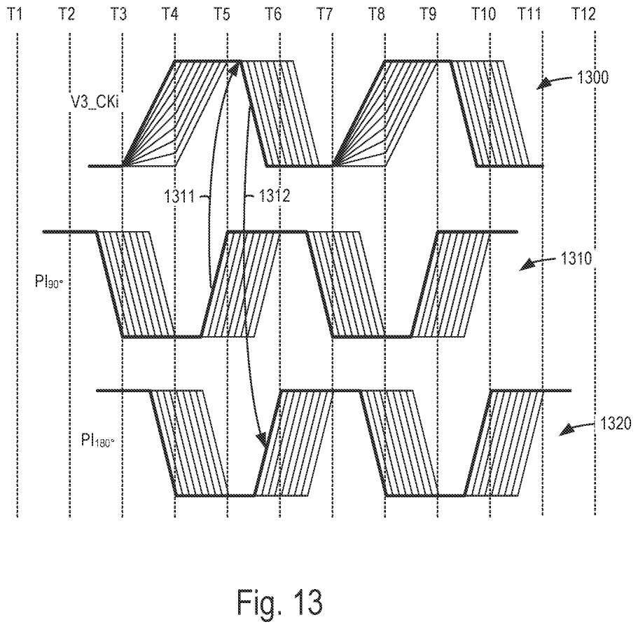

FIG. 14 depicts example plots 1400, 1410 and 1420 of the interpolated output clock V4_CKi, the input internal clock PI_{180°} and the output internal clock PI_{270°}, respectively, consistent with the interpolator cell 314 of FIG. 10, in accordance with various embodiments. In a first cycle, V4_CKi increases at a time between T4 and T5 based on k. As before, the time of the decrease is shifted correspondingly so that the duty cycle is fixed regardless of k. Additionally, the arrow 1411 shows that when PI_{180°} increases, the pulldown transistor is turned on so that the pulldown node (at V4_CKi) starts to discharge, after a small delay due to parasitic capacitance. PI_{180°} thus controls the time at which V4_CKi discharges. The arrow 1412 shows that when V4_CKi decreases, the output internal clock signal PI_{270°} increases, after a small delay due to parasitic capacitance. PI_{270°} is therefore essentially the inverse of V4_CKi with a small delay.

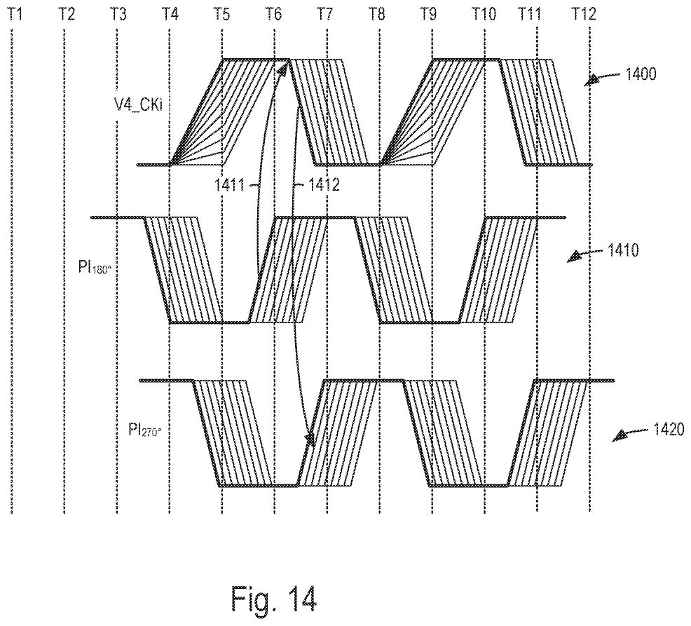

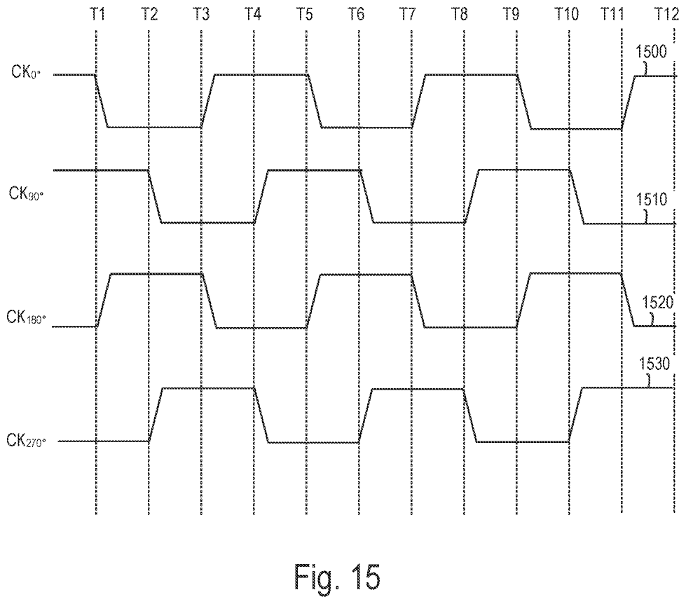

FIG. 15 depicts example plots 1500, 1510, 1520 and 1530 of CK_{0°}, CK_{90°}, CK_{180°} and CK_{270°}, respectively, consistent with FIGS. 7-14, in accordance with various embodiments. The plots depict voltage versus time, with the same time scale as FIGS. 11-14. As mentioned, these clock signals can be provided by the clock generator circuit 130, and are separated in phase from one another by equal amounts, e.g., 90 degrees. The increment between the time points on the time scale correspond to this phase difference. The clock signals alternate between high and low levels.

FIG. 16A depicts an example plot of the duty cycle of the internal clock signal PI0° (on the vertical axis) versus the decimal equivalent of a 7-bit a PI code (on the horizontal axis), consistent with FIGS. 7-10, in accordance with various embodiments. The PI code corresponds to different values of PI0°, e.g., ranging from 0-90 degrees. The plots in each of FIGS. 16A-16D show that the duty cycle is at or very close to the desired level of 50% throughout the range of the PI code. The plots are based on a simulated performance of a design prototype in which the proposed phase interpolator is implemented in a quarter-rate receiver architecture operating with quarter-phased 16 GHz clocks. The phase interpolation for each quadrant is done by varying the code of a 7-bit on-chip IDAC. By individually choosing pairs of the input clock phases, an additional 2-bit resolution gives a total of a 9-bit resolution of the output clock full-cycle (360°) phase rotation. The common mode voltage of the internal clock buffer is controlled by a 9-bit RDAC that can generate voltages between supply, 0.85 V, and ground. The duty-cycle of each of the output clock phases for varying codes is shown in FIGS. 16A-16D, showing a nearly constant duty-cycle independence of the codes. That is, the clock duty cycle may be constant and essentially independent of the PI code.

FIG. 16B depicts an example plot of the duty cycle of the internal clock signal PI_{90°} versus the decimal equivalent of a 7-bit a PI code, consistent with FIGS. 7-10, in accordance with various embodiments. The PI code corresponds to different values of PI_{90°}, e.g., ranging from 90-180 degrees.

FIG. 16C depicts an example plot of the duty cycle of the internal clock signal PI_{180°} versus the decimal equivalent of a 7-bit a PI code, consistent with FIGS. 7-10, in accordance with various embodiments. The PI code corresponds to different values of PI_{180°}, e.g., ranging from 180-270 degrees.

FIG. 16D depicts an example plot of the duty cycle of the internal clock signal PI_{270°} versus the decimal equivalent of a 7-bit a PI code, consistent with FIGS. 7-10, in accordance with various embodiments. The PI code corresponds to different values of PI_{270°}, e.g., ranging from 270-360 degrees.

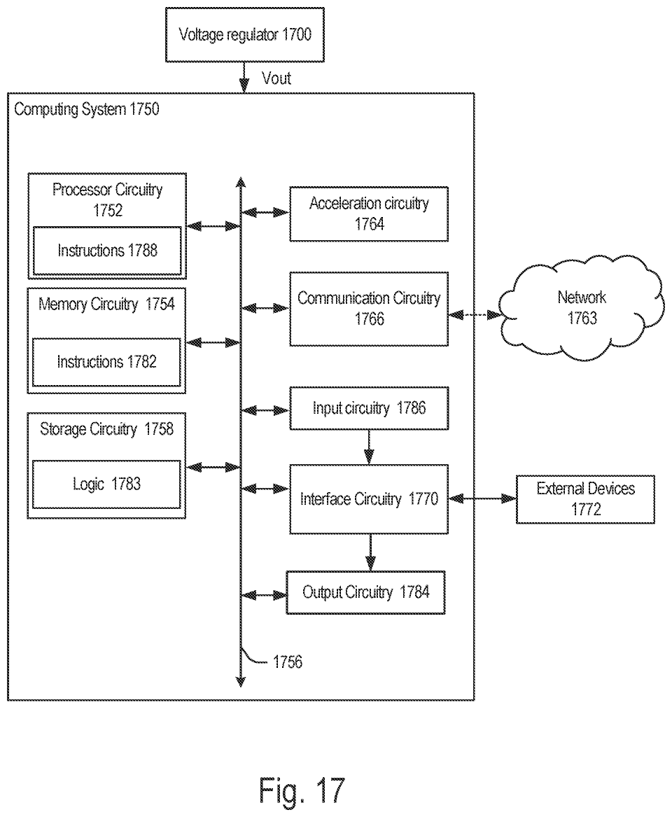

FIG. 17 illustrates an example of components that may be present in a computing system 1750 for implementing the techniques (e.g., operations, processes, methods, and methodologies) described herein. The phase interpolator cells including those in the circuit 300 of FIG. 3 may be implemented in the communication circuitry 1766, for example, or in any of the components of the computing system 1750.

The voltage regulator 1700 may provide a voltage Vout to one or more of the components of the computing system 1750. The memory circuitry 1754 may store instructions and the processor circuitry 1752 may execute the instructions to perform the functions described herein.

The computing system 1750 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1750, or as components otherwise incorporated within a chassis of a larger system. For one embodiment, at least one processor 1752 may be packaged together with computational logic 1782 and configured to practice aspects of various example embodiments described herein to form a System in Package (SiP) or a System on Chip (SoC).

The system 1750 includes processor circuitry in the form of one or more processors 1752. The processor circuitry 1752 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1752 may include one or more hardware accelerators (e.g., same or similar to acceleration circuitry 1764), which may be microprocessors, programmable processing devices (e.g., FPGA, ASIC, etc.), or the like. The one or more accelerators may include, for example, computer vision and/or deep learning accelerators. In some implementations, the processor circuitry 1752 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1752 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1752 may be coupled with or may include memory/storage and may be configured to execute instructions stored in the memory/storage to enable various applications or operating systems to run on the platform 1750. The processors (or cores) 1752 is configured to operate application software to provide a specific service to a user of the platform 1750. In some embodiments, the processor(s) 1752 may be a special-purpose processor(s)/controller(s) configured (or configurable) to operate according to the various embodiments herein.

As examples, the processor(s) 1752 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1752 may be a part of a system on a chip (SoC), System-in-Package (SiP), a multi-chip package (MCP), and/or the like, in which the processor(s) 1752 and other components are formed into a single integrated circuit, or a single package, such as the Edison™ or Galileo™ SoC boards from Intel® Corporation. Other examples of the processor(s) 1752 are mentioned elsewhere in the present disclosure.

The system 1750 may include or be coupled to acceleration circuitry 1764, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1764 may comprise logic blocks or logic fabric and other interconnected resources that may be programmed (configured) to perform various functions, such as the procedures, methods, functions, etc. of the various embodiments discussed herein. In such implementations, the acceleration circuitry 1764 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1752 and/or acceleration circuitry 1764 may include hardware elements specifically tailored for machine learning and/or artificial intelligence (AI) functionality. In these implementations, the processor circuitry 1752 and/or acceleration circuitry 1764 may be, or may include, an AI engine chip that can run many different kinds of AI instruction sets once loaded with the appropriate weightings and training code. Additionally or alternatively, the processor circuitry 1752 and/or acceleration circuitry 1764 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1752 and/or acceleration circuitry 1764 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 1770 provided by Huawei®, and/or the like. In some hardware-based implementations, individual subsystems of system 1750 may be operated by the respective AI accelerating co-processor(s), AI GPUs, TPUs, or hardware accelerators (e.g., FPGAS, ASICs, DSPs, SoCs, etc.), etc., that are configured with appropriate logic blocks, bit stream(s), etc. to perform their respective functions.

The system 1750 also includes system memory 1754. Any number of memory devices may be used to provide for a given amount of system memory. As examples, the memory 1754 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1754 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1754 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1758 provides persistent storage of information such as data, applications, operating systems and so forth. In an example, the storage 1758 may be implemented via a solid-state disk drive (SSDD) and/or high-speed electrically erasable memory (commonly referred to as “flash memory”). Other devices that may be used for the storage 1758 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1754 and/or storage circuitry 1758 may also incorporate three-dimensional (3D) cross-point (XPOINT) memories from Intel® and Micron®.

The memory circuitry 1754 and/or storage circuitry 1758 is/are configured to store computational logic 1783 in the form of software, firmware, microcode, or hardware-level instructions to implement the techniques described herein. The computational logic 1783 may be employed to store working copies and/or permanent copies of programming instructions, or data to create the programming instructions, for the operation of various components of system 1750 (e.g., drivers, libraries, application programming interfaces (APIs), etc.), an operating system of system 1750, one or more applications, and/or for carrying out the embodiments discussed herein. The computational logic 1783 may be stored or loaded into memory circuitry 1754 as instructions 1782, or data to create the instructions 1782, which are then accessed for execution by the processor circuitry 1752 to carry out the functions described herein. The processor circuitry 1752 and/or the acceleration circuitry 1764 accesses the memory circuitry 1754 and/or the storage circuitry 1758 over the interconnect (IX) 1756. The instructions 1782 direct the processor circuitry 1752 to perform a specific sequence or flow of actions, for example, as described with respect to flowchart(s) and block diagram(s) of operations and functionality depicted previously. The various elements may be implemented by assembler instructions supported by processor circuitry 1752 or high-level languages that may be compiled into instructions 1488, or data to create the instructions 1488, to be executed by the processor circuitry 1452. The permanent copy of the programming instructions may be placed into persistent storage devices of storage circuitry 1458 in the factory or in the field through, for example, a distribution medium (not shown), through a communication interface (e.g., from a distribution server (not shown)), over-the-air (OTA), or any combination thereof.

The IX 1756 couples the processor 1752 to communication circuitry 1766 for communications with other devices, such as a remote server (not shown) and the like. The communication circuitry 1766 is a hardware element, or collection of hardware elements, used to communicate over one or more networks 1763 and/or with other devices. In one example, communication circuitry 1766 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4. Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1766 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1756 also couples the processor 1752 to interface circuitry 1770 that is used to connect system 1750 with one or more external devices 1772. The external devices 1772 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1750, which are referred to as input circuitry 1786 and output circuitry 1784. The input circuitry 1786 and output circuitry 1784 include one or more user interfaces designed to enable user interaction with the platform 1750 and/or peripheral component interfaces designed to enable peripheral component interaction with the platform 1750. Input circuitry 1786 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1784 may be included to show information or otherwise convey information, such as sensor readings, actuator position(s), or other like information. Data and/or graphics may be displayed on one or more user interface components of the output circuitry 1784. Output circuitry 1784 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1450. The output circuitry 1484 may also include speakers and/or other audio emitting devices, printer(s), and/or the like. Additionally or alternatively, sensor(s) may be used as the input circuitry 1484 (e.g., an image capture device, motion capture device, or the like) and one or more actuators may be used as the output device circuitry 1784 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1750 may communicate over the IX 1756. The IX 1756 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1756 may be a proprietary bus, for example, used in a SoC based system.

The number, capability, and/or capacity of the elements of system 1750 may vary, depending on whether computing system 1750 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1450 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.
Example 1 includes an apparatus, comprising: a first interpolator cell in a series of interpolator cells, wherein the first interpolator cell comprises: a first path comprising a first current source and a first transistor; a second path comprising a second current source and a second transistor; and a pulldown path coupled to the first path and the second path at a pulldown node, wherein the pulldown path comprises a pulldown transistor having a control gate coupled to an output path of a previous interpolator cell in the series of interpolator cells.
Example 2 includes the apparatus of Example 1, wherein in the first interpolator cell, the pulldown node is coupled to an inverter, and an output path of the inverter is coupled to a control gate of a pulldown transistor in a pulldown path of a next interpolator cell in the series of interpolator cells.
Example 3 includes the apparatus of Example 2, wherein the first interpolator cell comprises a capacitor coupled between the pulldown node and the inverter, and Example X includes the apparatus further comprises a resistor coupled to a node which is between the capacitor and the inverter, wherein the resistor is coupled to a voltage generator.
Example 4 includes the apparatus of any one of Examples 1-3, wherein the pulldown node is to output an interpolated clock signal which is an interpolation of a clock signal received at the first transistor and a clock signal received at the second transistor.
Example 5 includes the apparatus of any one of Examples 1-4, wherein a signal at the pulldown node is configured to go low when a clock signal on the output path of the previous interpolator cell goes high.
Example 6 includes the apparatus of any one of Examples 1-5, further comprising a current digital-to-analog converter (IDAC), wherein the IDAC is to control the first current source to provide a current of k*Iref and to control the second current source to provide a current of (N−k)*Iref, Iref is a reference current, k is an integer, N is an integer and k≤N.
Example 7 includes the apparatus of Example 1, further comprising a current digital-to-analog converter (IDAC), wherein the IDAC is coupled to first and second current sources in each interpolator cell of the series of interpolator cells.
Example 8 includes the apparatus of any one of Examples 1-7, further comprising a clock generator circuit to provide a first clock signal with a first phase and a second clock signal with a second phase, wherein: the first clock signal is provided to a control gate of the first transistor; the second clock signal is provided to a control gate of the second transistor; the second phase lags the first phase by 360/m degrees; and m is a number of the interpolator cells in the series of interpolator cells.
Example 9 includes the apparatus of any one of Examples 1-8, further comprising a computing device in which the first interpolator cell is provided, wherein the computing device comprises at least one of an integrated circuit, a System on Chip, or a System in Package, and the computing device is to provide one or more of high-speed data communications, a phased array transmitter, a time-of-flight computation or data communications which synchronize a clock phase with respect to data.
Example 10 includes an apparatus, comprising: a plurality of circuits arranged in series, wherein each circuit of the plurality of circuits comprises: a first path comprising a first current source and a first clocked transistor in series; a second path comprising a second current source and a second clocked transistor in series; a pulldown path coupled to the first path and the second path at a pulldown node, wherein the pulldown path comprises a clocked transistor coupled to receive a clock signal generated by a previous circuit in the series of circuits; and an output path coupled to the pulldown node, wherein the output path is to provide a clock signal to a clocked transistor of a pulldown path of a next circuit in the series of circuits.
Example 11 includes the apparatus of Example 10, wherein the clock signals received by the clocked transistors of the pulldown paths of consecutive circuits of the plurality of circuit in the series are offset in phase from one another by 360/m degrees, and m is a number of the circuits in the plurality of circuits.
Example 12 includes the apparatus of Example 10 or 11, wherein the first and second clocked transistors of each circuit of the plurality of circuits are to receive first and second clock signals, respectively, from a clock generator circuit, the first and second clock signals received at each circuit are offset in phase from one another by 360/m degrees, and m is a number of the circuits in the plurality of circuits.
Example 13 includes the apparatus of Example 12, wherein the first clock signals received at consecutive circuits of the plurality of circuits in the series are offset in phase from one another by 360/m degrees, and the second clocked signals received at the consecutive circuits of the plurality of circuits in the series are offset in phase from one another by 360/m degrees.
Example 14 includes the apparatus of any one of Examples 10-13, further comprising a current digital-to-analog converter (IDAC), wherein the IDAC is to control the first current source of each circuit of the plurality of circuits to provide a current of k*Iref and to control the second current source each circuit of the plurality of circuits to provide a current of (N−k)*Iref, Iref is a reference current, k is an integer, N is an integer and k≤N.
Example 15 includes the apparatus of any one of Examples 10-14, wherein the pulldown node of each circuit of the plurality of circuits is to output a respective clock signal which is an interpolation of a clock signal received at the first clocked transistor and a clock signal received at the second clocked transistor, and the respective clock signals have respective phases which are offset by equal amounts for consecutive circuits of the plurality of circuits.
Example 16 includes an apparatus, comprising: a plurality of interpolator cells arranged in series, wherein each interpolator cell of the plurality of interpolator cells is to: output a respective interpolated clock signal having a respective phase from a respective output node of the interpolator cell; and output a respective internal clock signal having a respective phase from a respective output path of the interpolator cell to a next interpolator cell of the plurality of interpolator cells in the series, wherein the respective internal clock signal is to control discharging of the respective output node of the next interpolator cell; and a current digital-to-analog converter (IDAC) coupled to the plurality of interpolator cells, wherein the IDAC is to provide a current to charge up the respective output node of each interpolator cell.
Example 17 includes Example X includes the apparatus of Example 16, wherein the respective internal clock signals of consecutive interpolator cells arranged in the series are offset in phase from one another by an equal amount.
Example 18 includes Example X includes the apparatus of Example 17, wherein the equal amount is 360/m degrees, and m is a number of the interpolator cells in the plurality of interpolator cells.
Example 19 includes the apparatus of any one of Examples 16-18, wherein each interpolator cell of the plurality of interpolator cells comprises a pulldown path which is controlled by the respective internal clock signal output from a previous interpolator cell in the series.
Example 20 includes the apparatus of any one of Examples 16-19, wherein the respective interpolated clock signals of consecutive interpolator cells arranged in the series are offset in phase from one another by an equal amount.
Example 21 includes a method, comprising: at a first interpolator cell in a series of interpolator cell, receiving a clock signal generated by a previous interpolator cell in the series of interpolator cells and transmitting a clock signal to a next interpolator cell in the series of interpolator cells, wherein the clock signal generated by the previous interpolator cell is received at a pulldown transistor of the interpolator cell and the transmitted clock signal is provided to a pulldown transistor of the next interpolator cell.
Example 22 includes the method of Example 21, wherein: wherein the clock signal generated by the previous interpolator cell and the transmitted clock signal are offset in phase from one another by 360/m degrees, and m is a number of the interpolator cells in the series of interpolator cells.
Example 23 includes a non-transitory machine-readable storage including machine-readable instructions that, when executed, cause a processor or other circuit or computing device to implement the method of Example 21.
Example 24 includes a computer program comprising instructions which, when the program is executed by a computer, cause the computer to carry out the method of Example 21.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may.” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a first interpolator cell in a series of interpolator cells, wherein the first interpolator cell comprises:
a first path comprising a first current source and a first transistor;
a second path comprising a second current source and a second transistor; and
a pulldown path coupled to the first path and the second path at a pulldown node, wherein the pulldown path comprises a pulldown transistor having a control gate coupled to an output path of a previous interpolator cell in the series of interpolator cells.

2. The apparatus of claim 1, wherein in the first interpolator cell, the pulldown node is coupled to an inverter, and an output path of the inverter is coupled to a control gate of a pulldown transistor in a pulldown path of a next interpolator cell in the series of interpolator cells.

3. The apparatus of claim 2, wherein the first interpolator cell comprises a capacitor coupled between the pulldown node and the inverter, and the apparatus further comprises a resistor coupled to a node which is between the capacitor and the inverter, wherein the resistor is coupled to a voltage generator.

4. The apparatus of claim 1, wherein the pulldown node is to output an interpolated clock signal which is an interpolation of a clock signal received at the first transistor and a clock signal received at the second transistor.

5. The apparatus of claim 1, wherein a signal at the pulldown node is to go low when a clock signal on the output path of the previous interpolator cell goes high.

6. The apparatus of claim 1, further comprising a current digital-to-analog converter (IDAC), wherein the IDAC is to control the first current source to provide a current of k*Iref and to control the second current source to provide a current of (N−k)*Iref, Iref is a reference current, k is an integer, N is an integer and k≤N.

7. The apparatus of claim 1, further comprising a current digital-to-analog converter (IDAC), wherein the IDAC is coupled to first and second current sources in each interpolator cell of the series of interpolator cells.

8. The apparatus of claim 1, further comprising a clock generator circuit to provide a first clock signal with a first phase and a second clock signal with a second phase, wherein:
the first clock signal is provided to a control gate of the first transistor;
the second clock signal is provided to a control gate of the second transistor;
the second phase lags the first phase by 360/m degrees; and
m is a number of the interpolator cells in the series of interpolator cells.

9. The apparatus of claim 1, further comprising at least one of an integrated circuit, a System on Chip, a System in Package or a computing device in which the first interpolator cell is provided, wherein the computing device comprises at least one of a voltage regulator, a processor circuitry, a memory circuitry, a storage circuitry, a clock circuit, an acceleration circuitry, a communication circuitry, an input circuitry, an output circuitry, an interface circuitry or an external device.

10. An apparatus, comprising:
a plurality of circuits arranged in series, wherein each circuit of the plurality of circuits comprises:
a first path comprising a first current source and a first clocked transistor in series;
a second path comprising a second current source and a second clocked transistor in series;
a pulldown path coupled to the first path and the second path at a pulldown node, wherein the pulldown path comprises a clocked transistor coupled to receive a clock signal generated by a previous circuit in the series of circuits; and
an output path coupled to the pulldown node, wherein the output path is to provide a clock signal to a clocked transistor of a pulldown path of a next circuit in the series of circuits.

11. The apparatus of claim 10, wherein the clock signals received by the clocked transistors of the pulldown paths of consecutive circuits of the plurality of circuit in the series are offset in phase from one another by 360/m degrees, and m is a number of the circuits in the plurality of circuits.

12. The apparatus of claim 10, wherein the first and second clocked transistors of each circuit of the plurality of circuits are to receive first and second clock signals, respectively, from a clock generator circuit, the first and second clock signals received at each circuit are offset in phase from one another by 360/m degrees, and m is a number of the circuits in the plurality of circuits.

13. The apparatus of claim 12, wherein the first clock signals received at consecutive circuits of the plurality of circuits in the series are offset in phase from one another by 360/m degrees, and the second clocked signals received at the consecutive circuits of the plurality of circuits in the series are offset in phase from one another by 360/m degrees.

14. The apparatus of claim 10, further comprising a current digital-to-analog converter (IDAC), wherein the IDAC is to control the first current source of each circuit of the plurality of circuits to provide a current of k*Iref and to control the second current source each circuit of the plurality of circuits to provide a current of (N−k)*Iref, Iref is a reference current, k is an integer, N is an integer and k≤N.

15. The apparatus of claim 10, wherein the pulldown node of each circuit of the plurality of circuits is to output a respective clock signal which is an interpolation of a clock signal received at the first clocked transistor and a clock signal received at the second clocked transistor, and the respective clock signals have respective phases which are offset by equal amounts for consecutive circuits of the plurality of circuits.

16. An apparatus, comprising:
a plurality of interpolator cells arranged in series, wherein each interpolator cell of the plurality of interpolator cells is to:
output a respective interpolated clock signal having a respective phase from a respective output node of the interpolator cell; and
output a respective internal clock signal having a respective phase from a respective output path of the interpolator cell to a next interpolator cell of the plurality of interpolator cells in the series, wherein the respective internal clock signal is to control discharging of the respective output node of the next interpolator cell; and
a current digital-to-analog converter (IDAC) coupled to the plurality of interpolator cells, wherein the IDAC is to provide a current to charge up the respective output node of each interpolator cell.

17. The apparatus of claim 16, wherein the respective internal clock signals of consecutive interpolator cells arranged in the series are offset in phase from one another by an equal amount and have a duty-cycle which is independent of the phase offset.

18. The apparatus of claim 17, wherein the equal amount is 360/m degrees, and m is a number of the interpolator cells in the plurality of interpolator cells.

19. The apparatus of claim 16, wherein each interpolator cell of the plurality of interpolator cells comprises a pulldown path which is controlled by the respective internal clock signal output from a previous interpolator cell in the series.

20. The apparatus of claim 16, wherein the respective interpolated clock signals of consecutive interpolator cells arranged in the series are offset in phase from one another by an equal amount and have a duty-cycle which is independent of the phase offset.
